(19) United States
(12) Patent Application Publication
(10) Pub. No.: US 2010/0001315 A1
(43) Pub. Date: Jan. 7, 2010

(54) SEMICONDUCTOR DEVICE

(76) Inventors: Masaaki OKITA, Toyama (JP); Kazuyuki Sawada, Toyama (JP); Yuji Harada, Hyogo (JP); Saichirou Kaneko, Kyoto (JP); Hiroto Yamagiwa, Hyogo (JP)

Correspondence Address: MCDERMOTT WILL & EMERY LLP, 600 13TH STREET, NW, WASHINGTON, DC, 20005-3096, US

(21) Appl. No.: 12/473,604

(22) Filed: May 28, 2009

(30) Foreign Application Priority Data
Jul. 3, 2008 (JP) 2008-174731

(51) Int. Cl. H01L 29/739; H01L 29/78

(52) U.S. Cl. 257/139; 257/343; 257/E29.261; 257/E29.197

(57) ABSTRACT

A semiconductor device includes a first diffusion region of a second conductivity type formed in an upper portion of a semiconductor substrate of a first conductivity type, a second diffusion region formed in a surface portion of the first diffusion region, a third diffusion region of the second conductivity type formed a predetermined distance spaced apart from the second diffusion region in the surface portion of the semiconductor substrate, a fourth diffusion region of the first conductivity type formed adjacent to the third diffusion region and electrically connected to the third diffusion region, a gate electrode formed on a part between the first diffusion region and the third diffusion region, and an insulating film formed thereon. The impurity concentration of the first diffusion region is set higher than an impurity concentration at which a depletion region extending from an junction interface between the first diffusion region and the semiconductor substrate is formed in a part of the first diffusion region which is between the second diffusion region and the gate electrode when a voltage is applied to the second diffusion region.

### CROSS REFERENCE TO RELATED APPLICATIONS

This application claims priority under 35 U.S.C. §119(a) on Patent Application No. 2008-174731 filed in Japan on Jul. 3, 2008, the entire contents of which are hereby incorporated by reference.

### BACKGROUND

In power semiconductor devices used in power converters, power controllers, and the like, a switching element for on/off switching of current flow, such as a high breakdown voltage power transistor or the like is formed together with a control circuit and a protection circuit in a single substrate. This configuration achieves reduction in size and weight and high functionality, and therefore, are used in various fields of switching power supplies for various electronic equipment, such as office equipment, home appliances, and the like. The control circuit and the protection circuit are formed with an active element (e.g., a transistor element), a resistance element, a capacitive element, and the like.

The above power semiconductor devices are demanded to have a small voltage drop in an ON state for reducing power loss as far as possible Particularly, in the fields that requires high breakdown voltages, transistors employing a RESURF (Reduced Surface Field) structure are suitable.

As one example, the configuration and operation of a MOSFET (Metal Oxide Semiconductor Field Effect Transistor) disclosed in Japanese Patent No. 2529717 will be described below.

FIG. 10 shows a cross sectional configuration of the RESURFMOSFET formed on a semiconductor substrate.

As shown in FIG. 10, a semiconductor device 210 is formed using a semiconductor substrate 200 made of silicon (Si) of a first conductivity type.

In the upper portion of the semiconductor substrate 200, a second conductivity type extension drain 201 is formed. A second conductivity type drain region 202 is formed in the surface portion of the drain extension region 201.

In the surface portion of the semiconductor substrate 200, a second conductivity type source region 203 is formed with the drain extension region 201 interposed between it and the drain region 202, and with a predetermined distance left from the drain region 202.

In the surface portion of a part of the drain extension region 201 which is located between the drain region 202 and the source region 203, a first conductivity type buried region 204 electrically connected to the semiconductor substrate 200 is formed.

Further, a first conductivity type contact region 205 is formed in the surface portion of the semiconductor substrate 200 so as to be adjacent and electrically connected to the source region 203. In the surface portion of the semiconductor substrate 200, a first conductivity type well region 206 is also formed so as to surround the source region 203 and the contact region 205 and so as to be adjacent to the drain extension region 201.

In addition, an insulating film 207 of a silicon oxide film is formed on a part of the well region 206 which is located between the drain extension region 201 and the source region 203, and a gate electrode 208 made of polysilicon is formed thereon.

In the semiconductor device 210 thus configured, a voltage is applied between the drain region 202 and the source region 203, and a voltage equal to or higher than a specified voltage is applied between the gate electrode 208 and the source region 203 so that the gate electrode 208 has a high potential. This forms a channel in a strong inversion state in a region of the well region 206 which is immediately below the gate electrode 208, and accordingly, current flows between the drain region 202 and the source region 203 through the channel. Hereinafter, this state in which the current flows is called an ON state.

Further, in the semiconductor device 210, when the voltage applied between the gate electrode 208 and the source region 203 is lower than the specified voltage, the channel disappears, and a reverse bias voltage is applied between the well region 206 and the drain extension region 201. As a result, a pn junction is formed between the well region 206 and the drain extension region 201, and the current does not flow between the drain region 202 and the source region 203. Hereinafter, this state in which the current does not flow is called an OFF state.

Here, in the semiconductor device 210 shown in FIG. 10, the buried region 204 is formed in a portion of the drain extension region 201 which is located between the source region 203 and the drain region 202. For this reason, when a high voltage is applied between the drain region 202 and the source region 203, a depletion region is formed around the junction interface between the buried region 204 and the drain extension region 201 additionally, at the same time when a depletion region is formed around the junction interface between the drain extension region 201 and the semiconductor substrate 200.

Accordingly, in the configuration shown in FIG. 10, even if the impurity concentration of the drain extension region 201 is increased, the depletion regions in the drain extension region 201 can be maintained when compared with a configuration with no buried region 204. The depletion regions can absorb the potential difference between the drain region 202 and the source region 203.

Thus, the semiconductor substrate 200 having the RESURFMOSFET structure shown in FIG. 10 can maintain a high breakdown voltage. Further, the increased impurity concentration of the extension region 201 can reduce the electric resistance (on-resistance) between the drain region 202 and the source region 203.

### SUMMARY

However, production of the semiconductor device 210 shown in FIG. 10 may result in devices having remarkably low surge capacities.

In view of this, a semiconductor device that can ensure both a desired breakdown voltage and a surge capacity will be described below.

The inventors first studied the reason why the surge capacity decreases.

FIG. 11 shows the relationship (a solid line) between the electric conductivity and the breakdown voltage of the drain extension region 201 including the buried region 204, and the relationship (a broken line) between the electric conductivity and the surge capacity of the semiconductor device 210, according to the research by the inventors. The surge capacity means a capacity tolerable toward the surge voltage generated at a switching between the ON state and the OFF state.

The electric conductivity herein is defined by the following relational expression, and serves as an index indicating a ratio between the impurity concentration of the drain extension region 201 and the impurity concentration of the buried region 204.

Electric conductivity σ=1×10³×(1/RSed−3/RSb) [μS (microsiemens)]

RSed: the sheet resistance of the drain extension region 201 including the buried region 204

RSb: the sheet resistance of the buried region 204.

As shown in FIG. 11, the breakdown voltage of the semiconductor device 210 depends on the electric conductivity of the drain extension region 201. The breakdown voltage is a maximum when the electric conductivity is a predetermined value, and decreases as the electric conductivity deviates from the predetermined value.

Here, the electric conductivity is an index defined by the sheet resistances of the drain extension region 201 and buried region 204, as described previously.

Accordingly, the relationship between the electric conductivity and the breakdown voltage indicated in FIG. 11 indicates that the breakdown voltage decreases as the impurity concentration of the drain extension region 201 and buried region 204 deviates from the predetermined value. For this reason, in the semiconductor device 210, the impurity concentration of the drain extension region 201 and buried region 204 is adjusted so that the breakdown voltage of the semiconductor device 210 is a maximum.

In view of this, the present inventors studied in detail the relationship between the electric conductivity and the surge capacity, and found that, when the electric conductivity is decreased from the predetermined electric conductivity as a boundary at which the breakdown voltage is a maximum, the surge capacity of the semiconductor device 210 remarkably decreases. This is also shown in FIG. 11.

This indicates that where the sheet resistance of the drain extension region 201 or the buried region 204 varies, in other words, where the impurity concentration of the drain extension region 201 or the buried region 204 varies, the surge capacity may remarkably decrease.

In view of the foregoing, a semiconductor device of the present disclosure includes: a first diffusion region of a second conductivity type formed in an upper portion of a semiconductor substrate of a first conductivity type; a second diffusion region formed in a surface portion of the first diffusion region; a third diffusion region of the second conductivity type formed at a part a predetermined distance spaced apart from the second diffusion region in the surface portion of the semiconductor substrate with the first diffusion region interposed between it and the second diffusion region; a fourth diffusion region of the first conductivity type formed adjacent to the third diffusion region in the surface portion of the semiconductor substrate and electrically connected to the third diffusion region; and a gate electrode formed on a part between the first diffusion region and the third diffusion region with an insulating film interposed, wherein an impurity concentration of the first diffusion region is set higher than an impurity concentration adjusted so that a depletion region extending from an junction interface between the first diffusion region and the semiconductor substrate extends to a part of the first diffusion region which is between the second diffusion region and the gate electrode when a voltage is applied to the second diffusion region.

In the above semiconductor device, as will be described blow, a high breakdown voltage can be maintained, and a decrease in the surge capacity, which is caused by variation in impurity concentration of the first diffusion region, can be suppressed.

Conventionally, the impurity concentration of the first diffusion region is defined as a concentration at which the depletion region extending from the junction interface between the first diffusion region and the semiconductor substrate is formed in the entirety of the dominant part of the first diffusion region (in a more specific example, a part of the first diffusion region which is between the second diffusion region and the gate electrode). This concentration is a concentration set so that application of a predetermined voltage to the second diffusion region in a state where the semiconductor device is turned off depletes the first diffusion region and removes the electrons and holes in the first diffusion region to allow the breakdown voltage of the semiconductor device to be a maximum. However, where the concentration is set in this way, variation in concentration may remarkably decrease the surge capacity, as indicated in FIG. 11 as a novel understanding by the present inventors.

In contrast, in the semiconductor device of the present disclosure, the impurity concentration of the first diffusion region is set higher than that in the conventional device. This can maintain, even if the impurity concentration of the first diffusion region varies, the impurity concentration can be maintained within the range where the dependency of the surge capacity on the impurity concentration is comparatively small, thereby preventing a remarkable decrease in surge capacity.

It is preferable that the impurity concentration of the first diffusion region is set higher than an impurity concentration adjusted so that the depletion region extending from the junction interface between the first diffusion region and the semiconductor substrate extends in an entirety of the first diffusion region.

This concentration setting can ensure the above advantages.

Further, it is preferable that the impurity concentration of the first diffusion region is set higher than an impurity concentration at which a breakdown voltage of the semiconductor device is a maximum.

As described above, the surge capacity may decrease remarkably by variation in concentration around the concentration at which the breakdown voltage of the semiconductor device is a maximum. Hence, the impurity concentration of the first diffusion region may be set in the concentration range higher than the above concentration.

Preferably, the impurity concentration of the first diffusion region is set higher than an impurity concentration at which a variation amount of a surge capacity of the semiconductor device with respect to a variation amount of the impurity concentration of the first diffusion region is small.

As described above, the present inventors found that a region where variation in surge capacity with respect to variation in impurity concentration is relatively large and a region where the variation in surge capacity is small when compared therewith are present in the vicinity of the concentration conventionally set as the impurity concentration of the first diffusion region. In view of this, the impurity concentration of the first diffusion region is set in a region higher than the impurity concentration at the boundary therebetween. This can suppress a remarkable decrease in surge capacity, which is caused by a decrease in impurity concentration.

The above semiconductor device of the present disclosure can be utilized in general semiconductor devices utilizing the RESURF structure. As examples, a MOS transistor and an insulated gate bipolar transistor (IGBT) will be referred to below.

That is, in the semiconductor deice of the present disclosure, it is preferable that a MOS transistor is formed which uses the first diffusion region as an drain extension region, the second diffusion region as a drain region of the second conductivity type, the third diffusion region as a source region, and the fourth diffusion region as a contact region.

The impurity concentration of the drain extension region of the above MOS transistor is set higher than the conventionally defined concentration. This increases the margin for variation in impurity concentration of the drain extension region for the surge capacity. That is, a semiconductor device including the MOS transistor can ensure the surge capacity with a high breakdown voltage maintained.

Alternatively, in the semiconductor device of the present disclosure, it is preferable that an insulated gate bipolar transistor is formed which uses the first diffusion region as a base region, the second diffusion region as a collector region of the first conductivity type, the third diffusion region as an emitter region, and the fourth diffusion region as a contact region.

In this IGBT, the impurity concentration of the base region is set higher than the conventionally defined concentration. This increases the margin for variation in impurity concentration of the base region for the surge capacity. That is, a semiconductor device including the IGBT can ensure the surge capacity with a high breakdown voltage maintained.

In the semiconductor device of the present disclosure, preferably, a MOS transistor and an insulated gate bipolar transistor are formed which use the first diffusion region as a base/drain extension region, the second diffusion region as a contact/drain region including a collector region of the first conductivity type and a drain region of the second drain region of the second conductivity type, the third diffusion region as an emitter/source region, and the fourth diffusion region as a contact region.

Thus, the second diffusion region has the structure including the first conductivity type region and the second conductivity type region electrically connected to each other, with a result that the above MOS transistor and IGBT can be incorporated in a single semiconductor device.

Referring to high breakdown semiconductor switching elements, reduction in power loss caused in operation is demanded in general. In detail, the use of a MOS transistor, which has a large electric resistance in operation, increases power loss in the ON state when compared with the use of an IGBT. In contrast, the use of an IGBT increases power loss at switching between the ON state and the OFF state when compared with the use of a MOS transistor.

In contrast, a structure in which a MOS transistor and a IGBT are incorporated in a single semiconductor device can result in utilization of the IGBT, which has a low electrical resistance, in usual operation and the MOS transistor, which is advantageous in power loss at switching, at switching between the ON state and the OFF state. As a result, the structure in which both of them are incorporated can reduce the power loss when compared with a structure including either one of the MOS transistor or the IGBT.

It is preferable that an electric conductivity of the first diffusion region is equal to or larger than 180 μS and equal to or smaller than 210 μS.

The electric conductivity of the first diffusion region depends on the impurity concentration of the first diffusion region. When the impurity concentration is set so that the electric conductivity of the first diffusion region in the semiconductor device of the present disclosure falls in the above range, it is possible to suppress a significant decrease in surge capacity caused by variation in impurity concentration, and to suppress to a minimum a decrease in breakdown voltage caused by setting the impurity concentration higher than the conventionally set impurity concentration.

Further, it is preferable to form at least one buried region of the first conductivity type within the first diffusion region.

This extends the depletion region from the junction interface between the first diffusion region and the buried region, in addition to the depletion region from the junction interface between the first diffusion region and the semiconductor substrate. Accordingly, even with the first diffusion region having the increased impurity concentration, depletion of the first diffusion region can be ensured. Particularly, the dominant part of the first diffusion region can be entirely depleted. This can achieve maintenance of a high breakdown voltage and a decrease in electric resistance in operation.

Preferably, multiple ones of the at least one buried region are arranged at regular intervals.

This can remarkably obtain the above advantages obtained by providing the buried layer.

Further, it is preferable to set an electric conductivity of the first diffusion region including the at least one buried region equal to or larger than 180 μS and equal to or smaller than 210 μS.

When the electric conductivity, which is determined according to the sheet resistance of the buried layer and the sheet resistance of the first diffusion region, falls in the above range, it is possible to suppress a remarkable decrease in surge capacity caused by variation in impurity concentration and to suppress a decrease in breakdown voltage caused by the increased impurity concentration higher than the conventionally set concentration.

As described above, according to the semiconductor device of the present disclosure, the margin for variation in manufacture can be extended, and a desired surge capacity can be ensured with the high breakdown voltage of a semiconductor switching element having a high breakdown voltage maintained.

### BRIEF DESCRIPTION OF THE DRAWINGS

FIG. 1 is a schematic cross-sectional view showing a configuration of a semiconductor device in accordance with Example Embodiment 1.

FIG. 2 is a graph showing a relationship between the electric conductivity and the surge capacity in an extended drain region of the semiconductor device in accordance with Example Embodiment 1.

FIG. 3 is a graph showing a relationship between the electric conductivity and the breakdown voltage in the drain extension region of the semiconductor device in accordance with Example Embodiment 1.

FIG. 4 is a schematic cross-sectional view showing a configuration of a semiconductor device in accordance with Example Embodiment 2.

FIG. 5 is a schematic plan view showing a semiconductor device in accordance with Example Embodiment 3.

FIG. 6 is a schematic cross-sectional view showing a configuration of the semiconductor device in accordance with Example Embodiment 3, and shows a cross section taken along the line VI-VI′ in FIG. 5

FIG. 7 a schematic cross-sectional view showing a configuration of the semiconductor device in accordance with Example Embodiment 3, and shows a cross section taken along the line VII-VII′ in FIG. 5.

FIG. 8 a schematic cross-sectional view showing a semiconductor device in accordance with Example Embodiment 4.

FIG. 9 is a schematic cross-sectional view showing a semiconductor device in accordance with a modified example of Example Embodiment 4.

FIG. 10 is a schematic cross-sectional view showing a conventional semiconductor device.

FIG. 11 is a graph showing relationships between the electric conductivity and the breakdown voltage or the surge capacity in an drain extension region of a conventional semiconductor device.

### DETAILED DESCRIPTION

### Example Embodiment 1

A semiconductor device in accordance with Example Embodiment 1 will be described below with reference to the drawings. FIG. 1 schematically shows a cross section of an example semiconductor device 150, more specifically, a RESURFMOSFET structure formed on a semiconductor substrate.

As shown in FIG. 1, the semiconductor device 150 of the present example embodiment is formed using a semiconductor substrate 100 made of P-type silicon (Si) having an impurity concentration of about 1×10¹⁴ to 1×10¹⁷ cm⁻³.

In the surface portion of the semiconductor substrate 100, an N-type drain extension region 101 and a P-type well region 102 are formed. The impurity concentration of the P-type well region 102 is about 1×10¹⁶ to 1×10¹⁷ cm³.

An N-type source region 103 having a high impurity concentration is formed in a part of the surface portion of the P-type well region 102. A gate electrode 105 made of polysilicon is formed, with a gate oxide film 104 made of silicon oxide (SiO₂) interposed, on the surface of a part of the P-type well region 102 which is interposed between the N-type drain extension region 101 and the N-type source region 103.

In the surface portion of the P-type well region 102, a P-type contact region 106 is formed. The impurity concentration of the P-type contact region 106 is higher than that of the P-type well region 102. A source electrode 107 made of an aluminum alloy, such as AlSiCu or the like is formed on and across the surface portions of the P-type contact region 106 and the N-type source region 103. The source electrode 107 is electrically connected in common to the P-type contact region 106 and the N-type source region 103.

In the surface portion of the N-type drain extension region 101, an N-type drain region 108 is formed which has an impurity concentration higher than that of the N-type drain extension region 101. The N-type drain region 108 is located on the opposite side of the gate electrode 105 to the N-type source region 103. Further, a drain electrode 109 made of an aluminum alloy, such as AlSiCu or the like is formed on the N-type drain region 108, and is electrically connected to the N-type drain region 108.

In addition, isolations 110a and 110b (which may be collectively called an isolation 110) made of silicon oxide are formed in the surface portions of the N-type drain extension region 101 and the P-type well region 102, respectively, for isolating the transistors formed on the semiconductor substrate 100.

An interlayer insulating film 111 having a layered structure of silicon oxide and BPSG is formed so as to cover the N-type source region 103, the gate electrode 105, the P-type contact region 106, the isolation 110, and the like. The interlayer insulating film 111 electrically isolates the gate electrode 105, the source electrode 107, and the drain electrode 109 from one another. The drain electrode 109 and the source electrode 107 pass through the interlayer insulating film 111.

On the interlayer insulating film 111, a protection film 112 made of silicon nitride (SiN) is formed so as to cover the gate electrode 105 and the source electrode 107.

Referring herein to a MOS transistor having the RESURF structure shown in FIG. 10, the impurity concentration of the drain extension region 201 is set at a concentration at which the depletion region extending from the junction interface between the drain extension region 201 and the semiconductor substrate 200 is formed in the entirety of the dominant part of the drain extension region 201. A further specific example of the concentration is a concentration at which the depletion region extends to a part of the drain extension region 201 which is between the drain region 202 and the gate electrode 208. Because, setting at this concentration can make the breakdown voltage of a semiconductor device to be a maximum.

In contrast, in the semiconductor device 150 of the present example embodiment, the impurity concentration of the N-type drain extension region 101 is set higher than the impurity concentration at which the breakdown voltage of the semiconductor device is a maximum. Specifically, in the present example embodiment, the impurity concentration of the N-type drain extension region 101 is set at about 0.5×10¹⁶ to 1.0×10¹⁶ cm⁻³. It is noted that, in the conventional semiconductor device, the impurity concentration of the drain extension region is set in a range of 0.2×10¹⁶ to 0.4×10¹⁶ cm⁻³, for example.

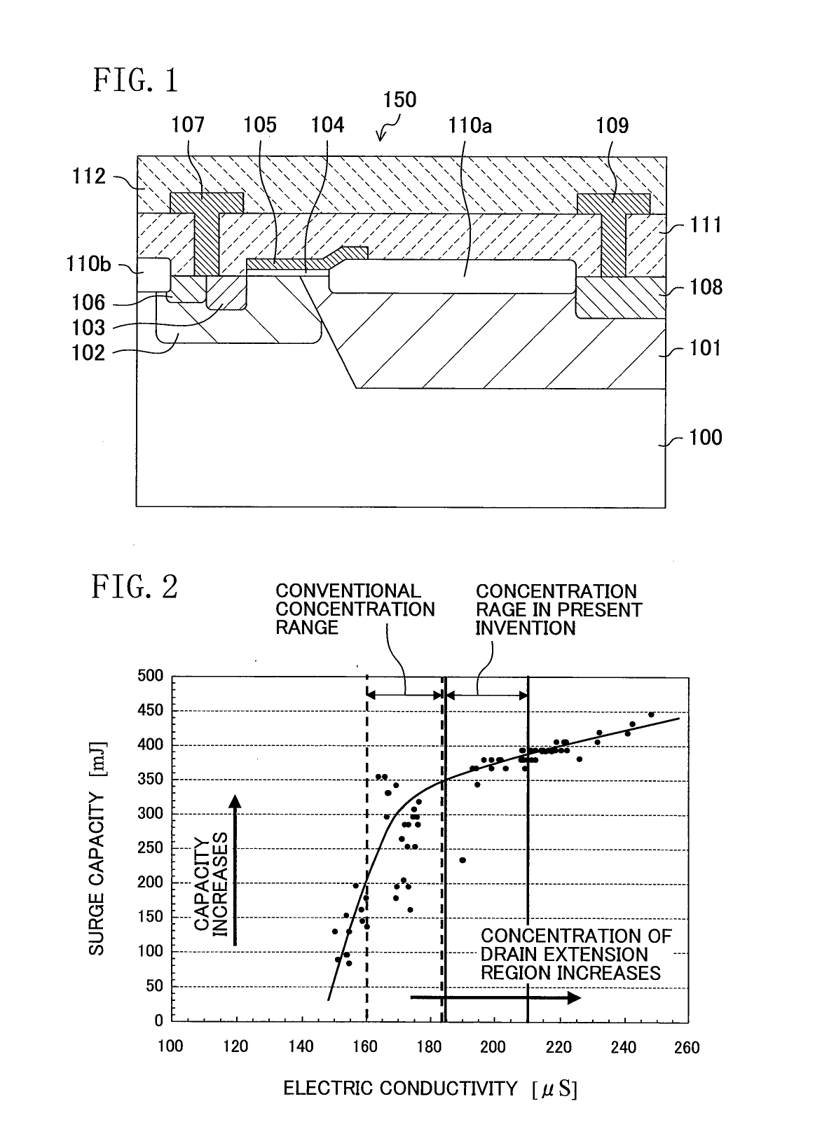

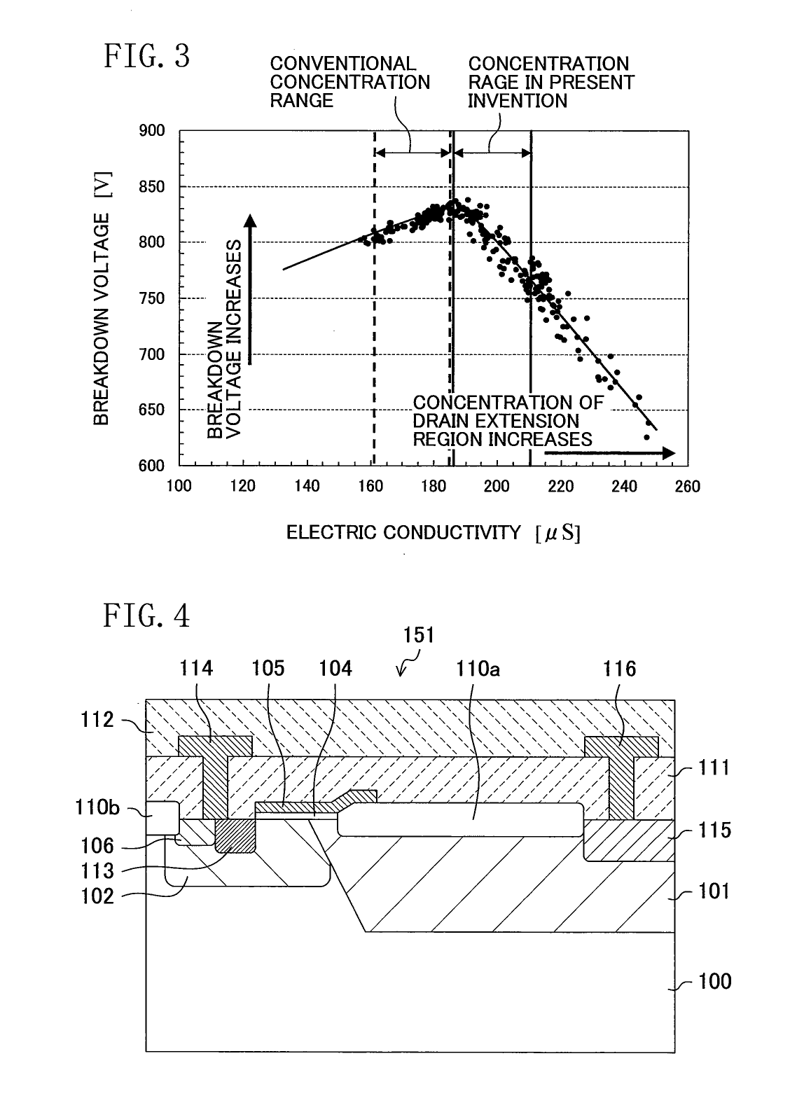

FIGS. 2 and 3 show the relationship between the electric conductivity and the surge capacity and the relationship between the electric conductivity and the breakdown voltage, respectively, of the N-type drain extension region 101 of the semiconductor device 150. It is noted that, as has been described previously, the electric conductivity is a value determined by the sheet resistance of the N-type drain extension region 101, and serves as an index indicating the impurity concentration of the N-type drain extension region 101.

Further, regions enclosed by the solid lines in FIGS. 2 and 3 indicate the electric conductivity range corresponding to the impurity concentration of the N-type drain extension region 101 in the present example embodiment. Here, the ranges are 180 μS or larger and 210 μS or smaller. In contrast, regions enclosed by the broken lines indicate the electric conductivity range corresponding to the impurity concentration that has been set conventionally.

As indicated in FIG. 2, where the concentration is in the conventional range, variation in electrical conductivity of the N-type drain extension region 101, which is caused by variation in manufacture and the like, may cause a remarkable decrease in surge capacity. In other words, the surge capacity may vary greatly in the conventional concentration range.

In contrast, in the case where the concentration range is set according to the present example embodiment, even if the impurity concentration of the N-type drain extension region 101 varies to cause variation in electric conductivity, a remarkable decrease in surge capacity cannot occur. This is because the concentration range is set in a range that can cause a comparatively small amount of variation in surge capacity, in view of the fact that a region where variation in surge capacity with respect to variation in impurity concentration is comparatively large and a region where the variation in surge capacity is small when compared therewith are present with a boundary drawn at a predetermined value. As a result, regardless of the presence of variation in impurity concentration, a high breakdown voltage can be maintained, and a desired surge capacity can be ensured.

In addition, as shown in FIG. 3, the impurity concentration of the N-type drain extension region 101 within the above range can lead to suppression of a decrease in breakdown voltage, which is caused by the increased impurity concentration of the N-type drain extension region 101, to a minimum.

As described above, according to the semiconductor device 150 of the present example embodiment, even if the impurity concentration of the N-type drain extension region 101 varies, a desired surge capacity can be ensured, while a high breakdown voltage can be maintained.

### Example Embodiment 2

Example Embodiment 2 will be described below with reference to the drawing. FIG. 4 schematically shows a cross sectional configuration of an example semiconductor device 151 in Example Embodiment 2. The semiconductor device 151 is an IGBT in a horizontal structure formed on a semiconductor substrate.

As shown in FIG. 4, the semiconductor device 151 has a structure similar to that of the semiconductor device 150 in FIG. 1. Therefore, only different points are described in detail, and further detailed description of the same components as those in FIG. 1 is omitted by putting the same reference numerals.

First, in FIG. 4, a P-type collector region 115 is formed, in place of the N-type drain region 108 in FIG. 1, in the surface portion of the N-type drain extension region 101. The impurity concentration of the P-type collector region 115 is higher than that of the N-type drain extension region 101. In place of the drain electrode 109 in FIG. 1, a collector electrode 116 made of an aluminum alloy, such as AlSiCu, or the like is formed on the P-type collector region 115.

Further, components of the semiconductor device in FIG. 4 corresponding to the N-type source region 103 and the source electrode 107 in FIG. 1 are called an emitter region 113 and an emitter electrode 114, respectively. That is, only the names are different.

In the semiconductor device 151, in the ON state, electron current flows from the emitter region 113 to the N-type drain extension region 101, and this current serves as base current of a pnp transistor formed with the P-type contact region 106, the N-type drain extension region 101, and the P-type collector region 115. When the base current flows, a large amount of holes are injected from the P-type collector region 115 to the N-type drain extension region 101. Accordingly, electrons are also injected from the emitter region 113 to the N-type drain extension region 101 for satisfying charge neutrality. Accordingly, both the electron density and the hole density of the N-type drain extension region 101 increase to remarkably reduce the on-resistance between the P-type collector region 105 and the emitter region 113.

Similarly to the case in Example Embodiment 1, setting the impurity concentration of the N-type drain extension region 101 higher than that in the conventional device can avoid a decrease in surge capacity.

Thus, the semiconductor device 151 in the present example embodiment, which is an IGBT in a horizontal structure, can also ensure a high breakdown voltage and a desired surge capacity. In addition, the on-resistance can be further reduced when compared with the semiconductor device 150 of Example Embodiment 1.

### Example Embodiment 3

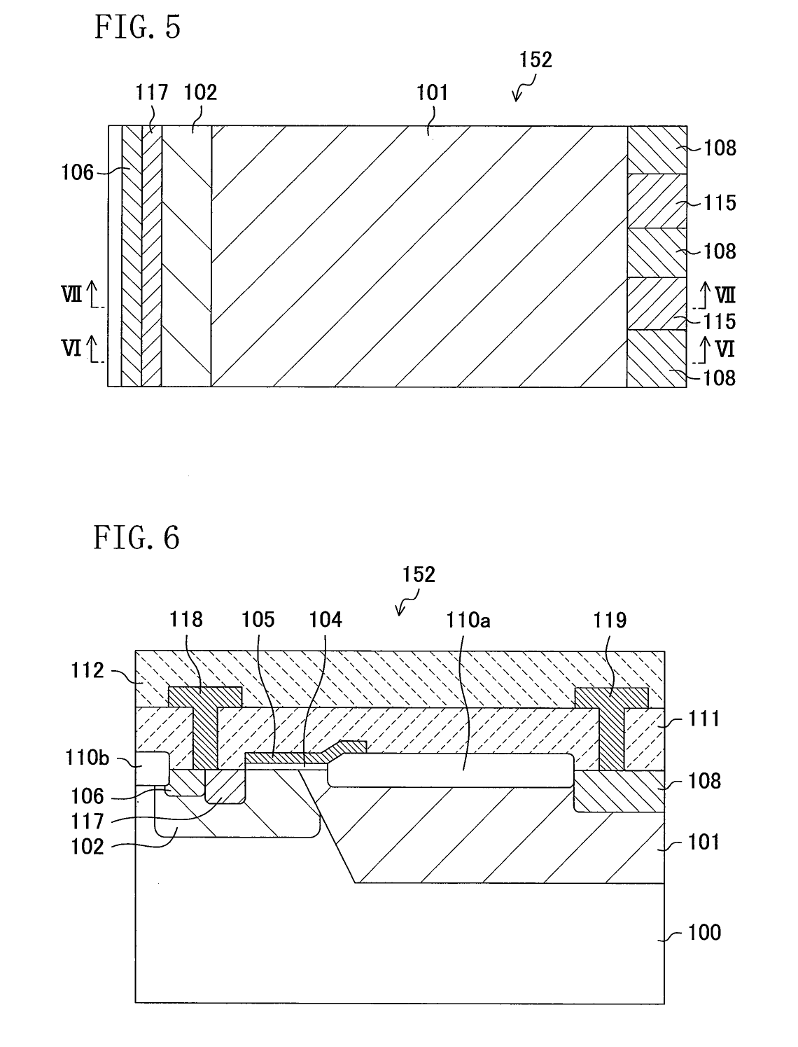

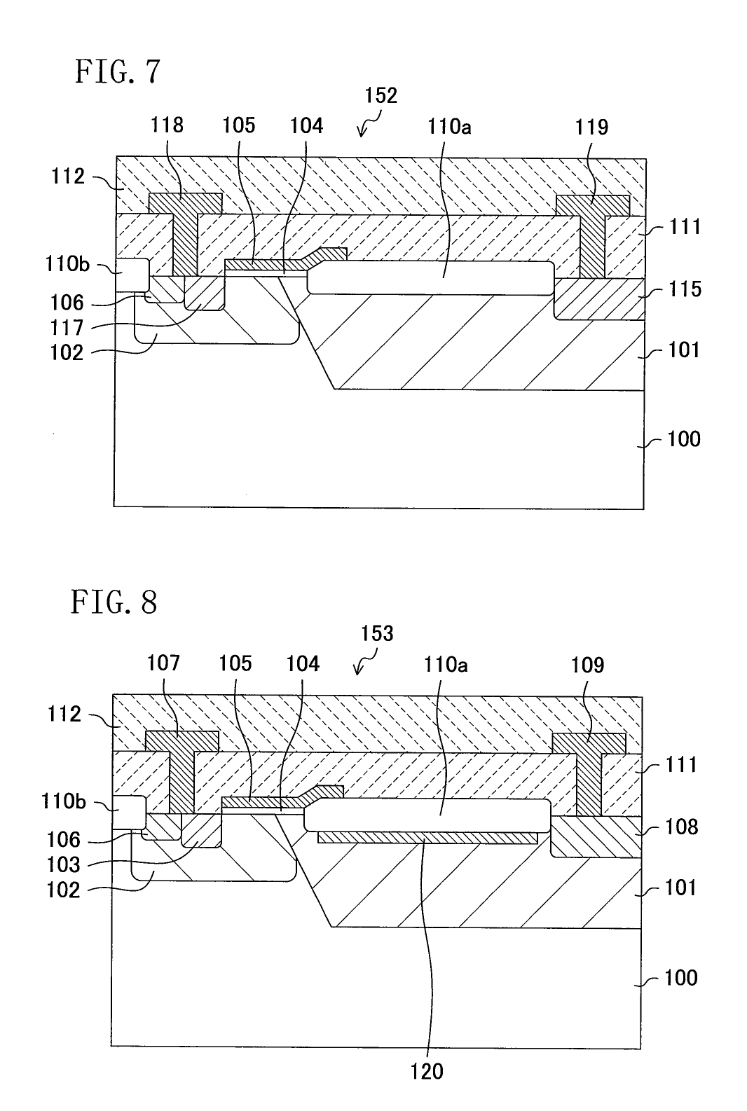

Example Embodiment 3 will be described below with reference to the drawings. FIG. 5 to FIG. 7 show a configuration of an example semiconductor device 152 of the present example embodiment. The semiconductor device 152 has, on a single semiconductor substrate, a structure on which MOS transistors in a horizontal structure having a cross section schematically shown in FIG. 6 and IGBTs in a horizontal structure having a cross section schematically shown in FIG. 7 are arranged alternatively as shown in a plan view of FIG. 5. FIG. 6 shows a cross section taken along the line VI-VI′ in FIG. 5, and FIG. 7 shows a cross section taken along the line VII-VII′ in FIG. 5.

Here, the configuration of the MOS transistors shown in FIG. 6 is the same as that of the semiconductor device 150 of Example Embodiment 1 shown in FIG. 1, and the configuration of the IGBTs shown in FIG. 7 is the same as that of the semiconductor device 151 of Example Embodiment 2 shown in FIG. 4.

It is noted that the N-type source region 103 in FIG. 1 and the emitter region 113 in FIG. 4 correspond to an emitter/source region 117 formed across the MOS transistors and the IGBTs arranged alternatively. In place of the source electrode 107 and the emitter electrode 114, an emitter/source electrode 118 is formed as an electrode formed on and connected in common to the emitter/source region 117 and the P-type contact region 106.

The N-type drain regions 108 and P-type collector regions 115 having an impurity concentration higher than that of the N-type drain extension region 101 are the same as those shown in FIGS. 1 and 4, respectively. However, as shown in FIG. 5, the N-type drain regions 108 and the P-type collector regions 115 in the semiconductor device 152 of the present example embodiment are arranged alternatively in a direction of the principal plane of the semiconductor substrate 100, and a corrector/drain electrode 119 is formed so as to electrically connect them to each other. The collector/drain electrode 119 is made of an aluminum alloy, such as AlSiCu or the like.

To components except the above described components, the same reference numerals are assigned as those in FIGS. 1 and 4, and no detailed description will be given herein.

As shown in FIGS. 5 to 7, in the semiconductor device 152 of the present example embodiment, the N-type drain regions 108 and the P-type collector regions 115 are formed in the surface portion of the N-type drain extension region 101 so as to be electrically connected to each other through the collector/drain electrode 119. In this way, two kinds of transistors of the MOS transistors and the IGBTs in the RESURF structures, which are electrically connected to each other in parallel, are incorporated.

Accordingly, the semiconductor device 152 can selectively utilize the IGBTs, which are advantageous in power loss in a conduction state, in the normal ON state, and the MOS transistors, which are advantageous in power loss at switching, at switching between the ON state and the OFF state.

As a result, the semiconductor device 152 of the present example embodiment can reduce the power loss when compared with both the semiconductor device 150 of Example Embodiment 1 and the semiconductor device 151 of Example Embodiment 2.

In addition, similarly to the case of Example Embodiment 1, a decrease in surge capacity can be avoided by setting the impurity concentration of the N-type drain extension region 101 higher than the conventionally set concentration.

### Example Embodiment 4

Example Embodiment 4 will be described with reference to the drawing. FIG. 8 schematically shows a cross-sectional configuration of an example semiconductor device 153 of the present example embodiment.

The semiconductor device 153 shown in FIG. 8 has a configuration in which a P-type buried region 120 formed in the surface portion of the N-type drain extension region 101 is added to the semiconductor device 150 of Example Embodiment 1 shown in FIG. 1. The P-type buried region 120 has a thickness of about 1.0 μm, and an impurity concentration in a range of about 1×10¹⁶ to 1×10¹⁷ cm⁻³. Further, the P-type buried region 120 is electrically connected to the semiconductor substrate 100, and is formed so as to extend substantially in parallel to the principal plane of the semiconductor substrate 100.

The other components are the same as those shown in FIG. 1. Therefore, the same reference numerals are used, and no detailed description will be given here.

According to the semiconductor device 153 in FIG. 8, by forming the P-type buried region 120 in the surface portion of the N-type drain extension region 101, application of a high voltage between the drain electrode 109 and the source electrode 107 in the OFF state causes a depletion region from the junction interface between the N-type drain extension region 101 and the P-type buried region 120 to extend, in addition to a depletion region from the junction interface between the N-type drain extension region 101 and the semiconductor substrate 100. This can result in depletion of the entire N-type drain extension region 101 even with the increased impurity concentration of the N-type drain extension region 101. As a result, the depletion region can absorb the potential difference between the drain electrode 109 and the source electrode 107.

Hence, in the semiconductor device 153 of the present example embodiment, the impurity concentration of the N-type extension region 101 can be set higher than that in the semiconductor device 150 of Example Embodiment 1, thereby reducing the electric resistance in operation.

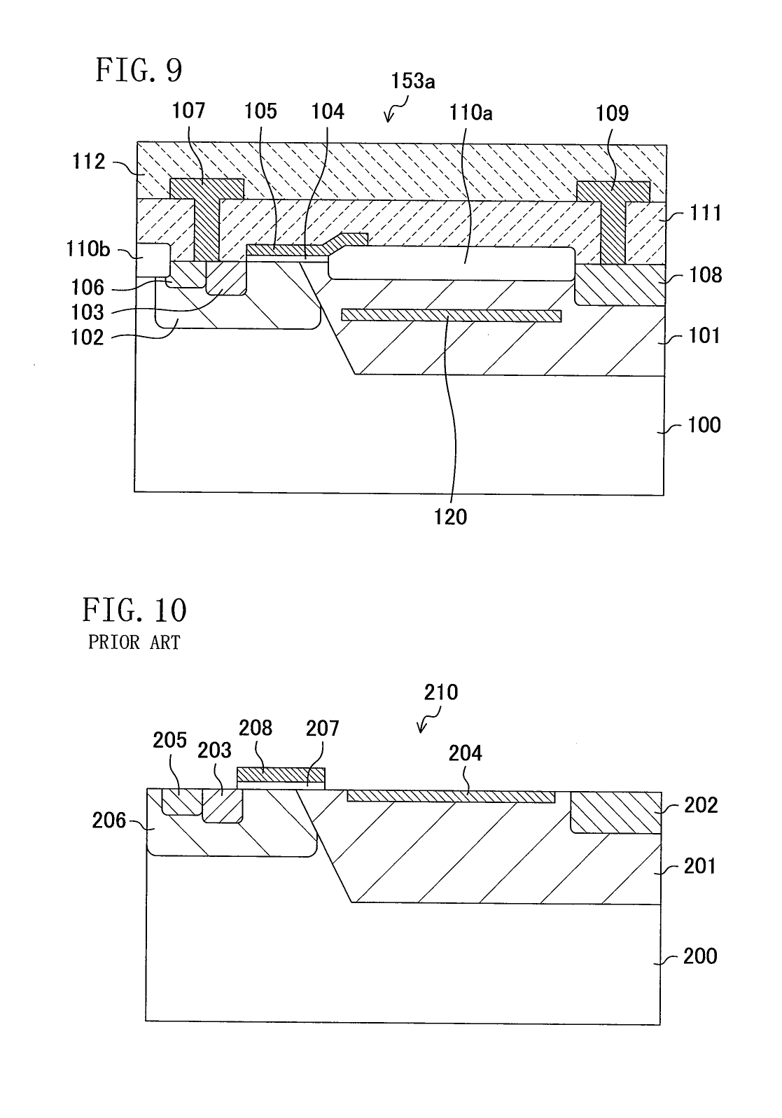

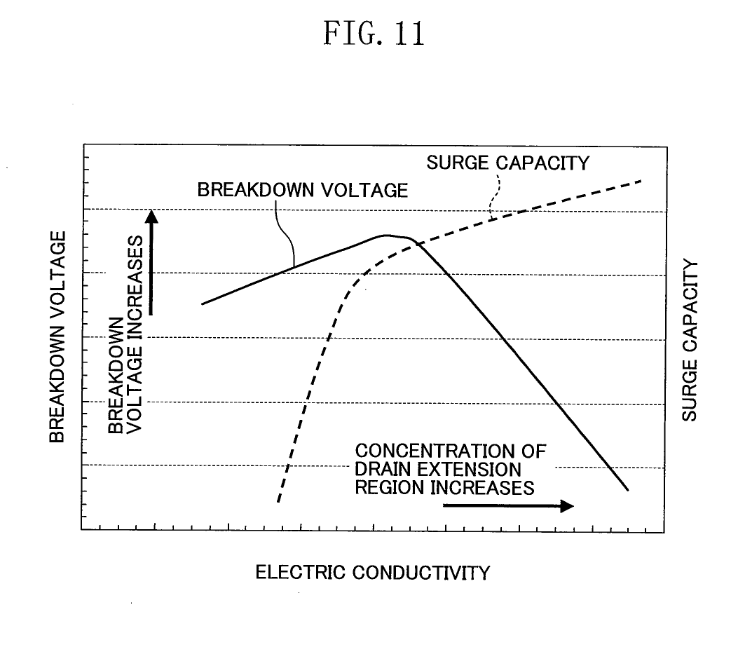

Referring to a modified example of the present example embodiment, as shown in FIG. 9, the P-type buried region 120 may be formed in a part of the N-type drain extension region 101 which is located at a predetermined depth from its surface, rather than the surface portion of the N-type drain extension region 101. Accordingly, the area of the contact face between the N-type drain extension region 101 and the P-type buried region 120 can be increased. This can encourage extension of the depletion regions from the junction interfaces in applying a high voltage between the drain electrode 109 and the source electrode 107 in the OFF state. As a result, in a semiconductor device 153 shown in FIG. 9, the impurity concentration of the N-type extension region 101 can be set higher than that in the semiconductor device 153 shown in FIG. 8, thereby further reducing the electric resistance.

In another example embodiment, a plurality of P-type buried regions 120 electrically connected to the semiconductor substrate 100 may be formed at predetermined regular intervals in the N-type drain extension region 101. This can provide a further increased impurity concentration of the N-type drain extension region 101, thereby further reducing the electric resistance.

In addition, in the present example embodiment, in the case where the impurity concentration of the P-type buried region 120 is 3.0×10¹⁶ cm⁻³, for example, the impurity concentration of the N-type drain extension region 101 is preferably 2.0×10¹⁶ cm⁻³ or higher and 2.1×10¹⁶ cm⁻³ or lower. By doing so, the electric conductivity of the N-type drain extension region 101 can be set in a range of 180 μS to 210 μS. It is noted that the impurity concentration of an N-type drain extension region in a conventional semiconductor device having a similar configuration is in a range from 2.3×10¹⁶ to 2.5×10¹⁶ cm⁻³.

Hence, as shown in FIGS. 2 and 3, a lowering of the breakdown voltage of the semiconductor device, which is caused by increasing the impurity concentration of the N-type drain extension region 101 higher than a predetermined concentration, can be suppressed to a minimum.

Moreover, the present example embodiment refers to the case where the P-type buried region 120 is added to the semiconductor device 150 of Example Embodiment 1. However, the same advantages can be obtained by forming the P-type buried region 120 within the N-type drain extension region 101 in the semiconductor device 151 of Example Embodiment 2 and the like.

What is claimed is:

1. A semiconductor device, comprising:
a first diffusion region of a second conductivity type formed in an upper portion of a semiconductor substrate of a first conductivity type;
a second diffusion region formed in a surface portion of the first diffusion region;
a third diffusion region of the second conductivity type formed at a part a predetermined distance spaced apart from the second diffusion region in the surface portion of the semiconductor substrate with the first diffusion region interposed between it and the second diffusion region;
a fourth diffusion region of the first conductivity type formed adjacent to the third diffusion region in the surface portion of the semiconductor substrate and electrically connected to the third diffusion region; and
a gate electrode formed on a part between the first diffusion region and the third diffusion region with an insulating film interposed,
wherein an impurity concentration of the first diffusion region is set higher than an impurity concentration adjusted so that a depletion region extending from an junction interface between the first diffusion region and the semiconductor substrate extends to a part of the first diffusion region which is between the second diffusion region and the gate electrode when a voltage is applied to the second diffusion region.

2. The device of claim 1, wherein
the impurity concentration of the first diffusion region is set higher than an impurity concentration adjusted so that the depletion region extending from the junction interface between the first diffusion region and the semiconductor substrate extends in an entirety of the first diffusion region.

3. The device of claim 1, wherein
the impurity concentration of the first diffusion region is set higher than an impurity concentration at which a breakdown voltage of the semiconductor device is a maximum.

4. The device of claim 1, wherein
the impurity concentration of the first diffusion region is set higher than an impurity concentration at which a variation amount of a surge capacity of the semiconductor device with respect to a variation amount of the impurity concentration of the first diffusion region is small.

5. The device of claim 1, wherein
a MOS transistor is formed which uses the first diffusion region as an drain extension region, the second diffusion region as a drain region of the second conductivity type, the third diffusion region as a source region, and the fourth diffusion region as a contact region.

6. The device of claim 1, wherein
an insulated gate bipolar transistor is formed which uses the first diffusion region as a base region, the second diffusion region as a collector region of the first conductivity type, the third diffusion region as an emitter region, and the fourth diffusion region as a contact region.

7. The device of claim 1, wherein
a MOS transistor and an insulated gate bipolar transistor are formed which use the first diffusion region as a base/drain extension region, the second diffusion region as a contact/drain region including a collector region of the first conductivity type and a drain region of the second drain region of the second conductivity type, the third diffusion region as an emitter/source region, and the fourth diffusion region as a contact region.

8. The device of claim 1, wherein
an electric conductivity of the first diffusion region is equal to or larger than 180 μS and equal to or smaller than 210 μS.

9. The device of claim 1, wherein
at least one buried region of the first conductivity type is formed within the first diffusion region.

10. The device of claim 9, wherein
multiple ones of the at least one buried region are arranged at regular intervals.

11. The device of claim 9, wherein
an electric conductivity of the first diffusion region including the at least one buried region is equal to or larger than 180 μS and equal to or smaller than 210 μS.
